(19) United States
(12) Patent Application Publication
(10) Pub. No.: US 2026/0086127 A1
(43) Pub. Date: Mar. 26, 2026

(54) CURRENT SENSOR

(71) Applicant: Asahi Kasei Microdevices Corporation, Tokyo (JP)

(72) Inventor: Yuta SUZUKI, Tokyo (JP)

(21) Appl. No.: 19/330,755

(22) Filed: Sep. 16, 2025

(30) Foreign Application Priority Data
Sep. 24, 2024 (JP) 2024-165451
Jul. 14, 2025 (JP) 2025-117685

(51) Int. Cl. G01R 15/20; G01R 19/00

(52) U.S. Cl. CPC G01R 15/207; G01R 15/202; G01R 19/00

(57) ABSTRACT

A current sensor includes: at least one magnetoelectric conversion unit; a first lead frame including a first terminal portion and a conductor portion; a signal processing IC; a second lead frame including a second terminal portion; and an encapsulating portion which encapsulates, by using mold resin, the at least one magnetoelectric conversion unit, the conductor portion, the signal processing IC, and a part of the second lead frame. 523×T_{ds}⁻¹×ε^{0.08}<400 is satisfied where T_{ds} denotes the shorter distance of distances from a first side surface of the encapsulating portion exposing the first terminal portion to the holding portion or to the signal processing IC; and ε denotes a relative permittivity of the mold resin.

The contents of the following patent application(s) are incorporated herein by reference:
NO. 2024-165451 filed in JP on Sep. 24, 2024
NO. 2025-117685 filed in JP on Jul. 14, 2025.

### BACKGROUND

### 1. Technical Field

The present invention relates to a current sensor.

### 2. Related Art

Patent Document 1 discloses a semiconductor device in which, in order to secure a minimum creepage distance, no suspension lead is exposed from a wall surface of a resin encapsulation in a corner part where no suspension lead is arranged.

### RELATED ART DOCUMENTS

### Patent Document

Patent Document 1: Japanese Patent Application Publication No. 2016-152298

### BRIEF DESCRIPTION OF THE DRAWINGS

FIG. 1A is a schematic plan view of a current sensor according to a present embodiment as seen from a ceiling face side (a z axis direction).

FIG. 1B is an A-A line sectional view of the current sensor shown in FIG. 1A.

FIG. 1C is an A-A line sectional view of a first variation of the current sensor according to the present embodiment.

FIG. 1D is an A-A line sectional view of a second variation of the current sensor according to the present embodiment.

FIG. 1E is an A-A line sectional view of a third variation of the current sensor according to the present embodiment.

FIG. 1F is a schematic plan view of a fourth variation of the current sensor according to the present embodiment as seen from the ceiling face side (the z axis direction).

FIG. 1G is an A-A line sectional view of the fourth variation of the current sensor according to the present embodiment.

FIG. 2 is a drawing showing a result based on Expression 2 representing a relationship between an electric field E on a surface of an encapsulating portion and a distance T_{ds} and a result based on a finite element method.

FIG. 3A is a drawing showing an example of a distribution of magnitudes of the electric field E generated by a partial discharge occurring between a holding portion and a conductor portion when T_{ds}=0.6.

FIG. 3B is a drawing showing an example of a distribution of magnitudes of the electric field E generated by a partial discharge occurring between a holding portion 151 and a conductor portion 141 when T_{ds}=1.6 mm.

FIG. 4 is a drawing showing a result based on Expression 2 representing a relationship between an electric field E on a surface of an encapsulating portion and a relative permittivity ε, while C=523, x=−1, y=0.08, and T_{ds}=0.6, and a result based on a finite element method.

FIG. 5 is a drawing showing a result based on Expression 3 representing a relationship between the electric field E on a surface of an encapsulating portion and a distance T_{b}, while C=470, x=−1, and y=0.08, and a result based on the finite element method.

FIG. 6 is a drawing showing a result based on Expression 3 representing a relationship between the electric field E on a surface of the encapsulating portion and the relative permittivity ε, while C=470, x=−1, y=0.08, and T_{b}=1.37 mm, and a result based on the finite element method.

FIG. 7A is a drawing showing a distribution of magnitudes of an electric field generated between the holding portion and the conductor portion when ε=12, while C=470, x=−1, y=0.08, and T_{b}=1.37 mm.

FIG. 7B is a drawing showing a distribution of magnitudes of an electric field generated between the holding portion and the conductor portion when ε=2, while C=470, x=−1, y=0.08, and T_{b}=1.37 mm.

FIG. 8 is a drawing showing a result based on Expression 4 representing a relationship between the electric field E on a surface of the encapsulating portion and a distance Tₜ, while C=280, x=−0.2, and y=0.12, and a result based on the finite element method.

FIG. 9 is a drawing showing a result based on Expression 4 representing a relationship between the electric field E on a surface of the encapsulating portion and the relative permittivity ε, while C=280, x=−0.2, y=0.12, and Tₜ=0.63 mm, and a result based on the finite element method.

FIG. 10 is a drawing showing a condition table of samples created as examples.

FIG. 11 is a drawing showing creepage discharge generated voltage of each of the samples with respect to Expression 2, Expression 3, and Expression 4.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

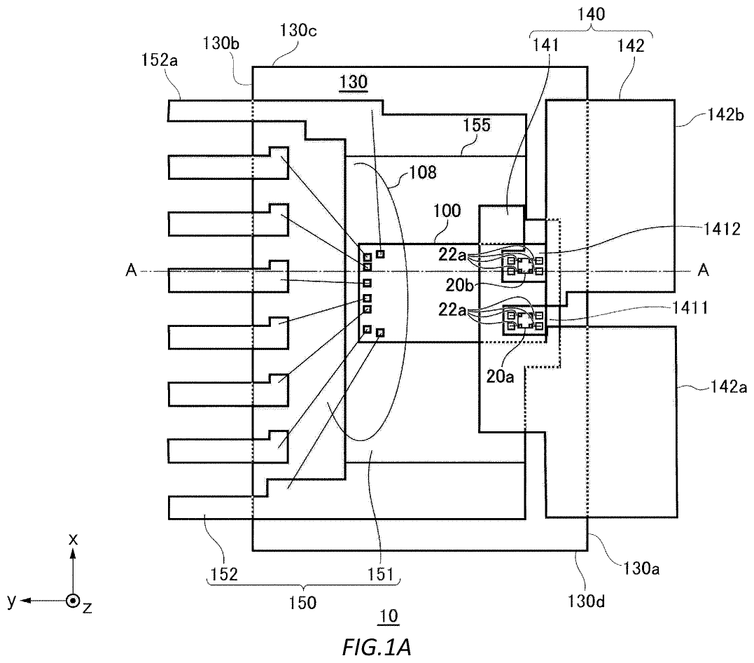

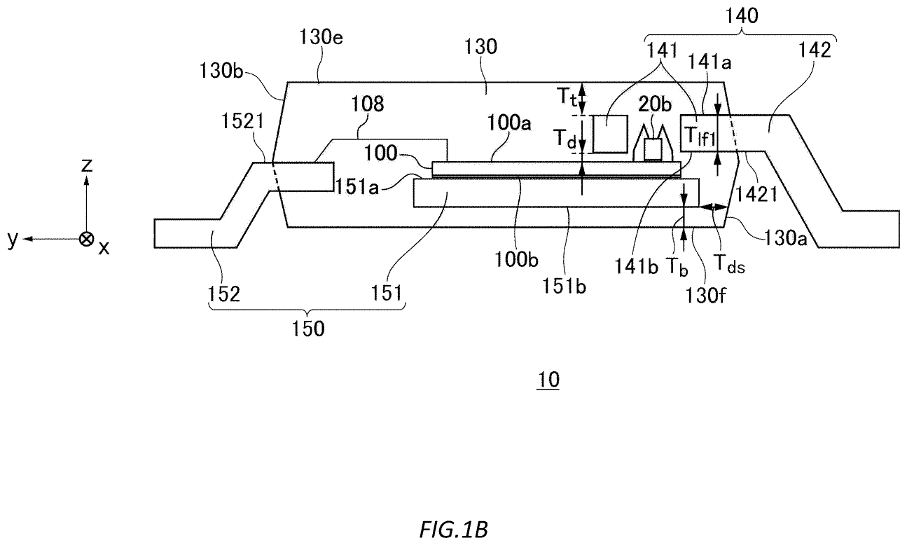

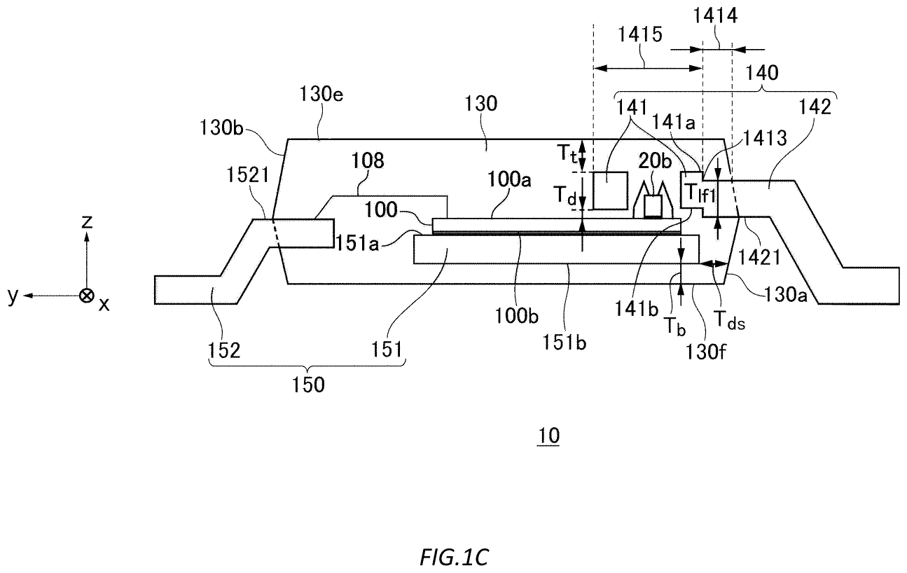

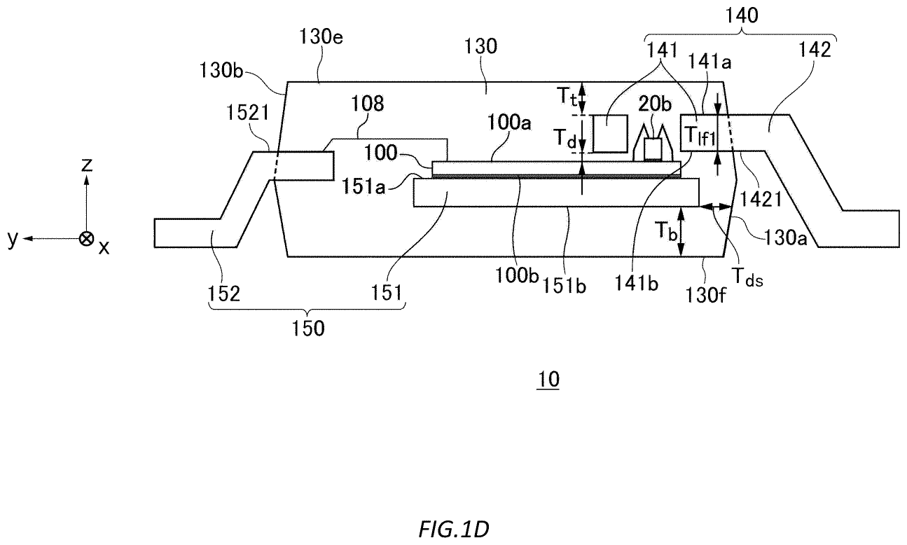

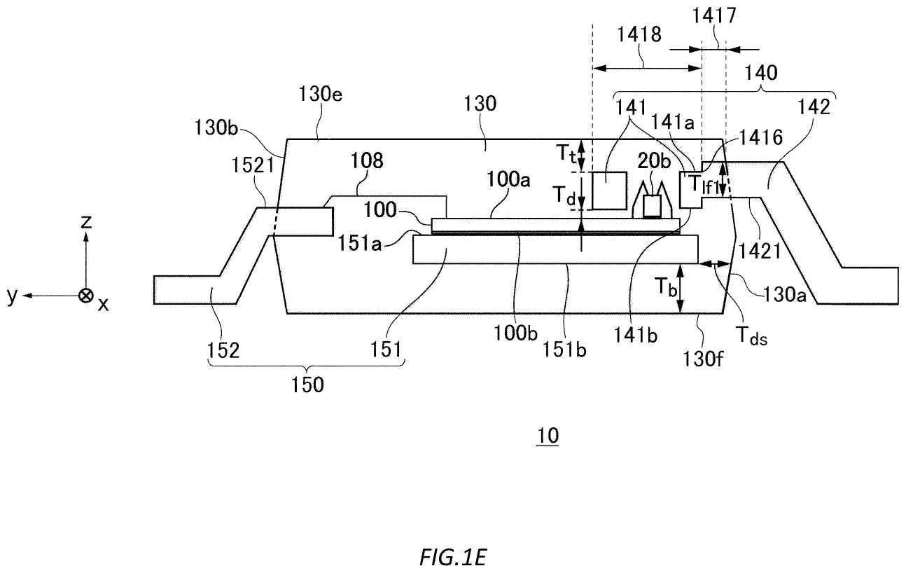

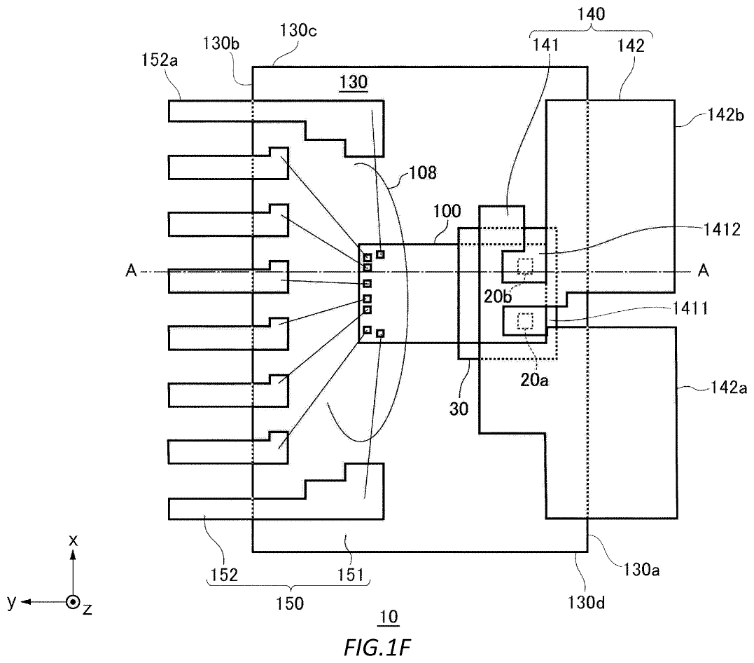

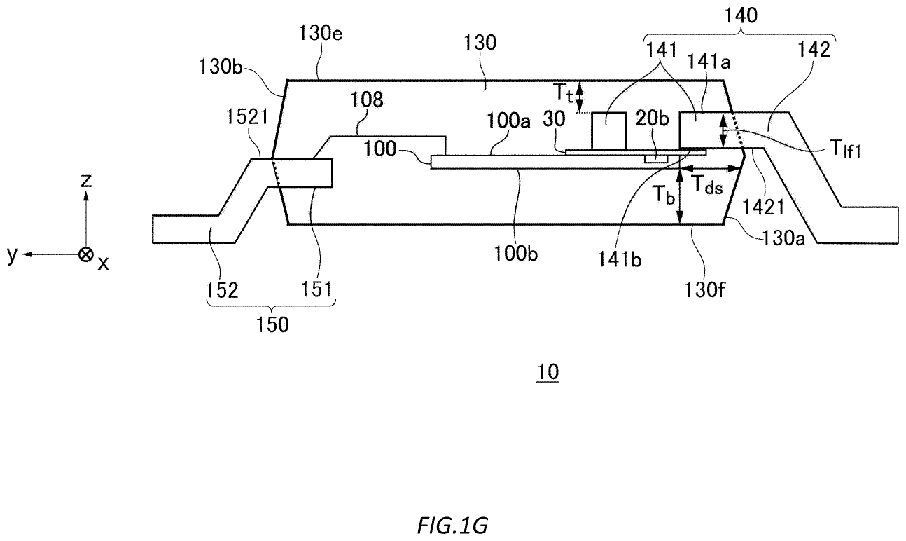

FIG. 1A and FIG. 1B show an interior configuration of a semiconductor package that functions as a current sensor 10 according to a present embodiment. FIG. 1A is a schematic plan view of a current sensor 10 according to the present embodiment as seen from a ceiling face side (the z axis direction). FIG. 1B is an A-A line sectional view of the current sensor 10 shown in FIG. 1A.

As for coordinates, in FIG. 1A the direction from the bottom up parallel to the drawing page is defined as an x axis direction; the direction from the right to the left parallel to the drawing page is defined as a y axis direction; and the direction from the depth of the page toward the viewer perpendicular to the drawing page is defined as a z axis direction. Any one of axes of an x axis, a y axis, and a z axis is orthogonal to the other axes.

The current sensor 10 comprises a signal processing IC 100, a magnetoelectric conversion element 20a, a magnetoelectric conversion element 20b, a lead frame 140 on the current conductor side, a lead frame 150 on the signal terminal side, and an encapsulating portion 130.

The lead frame 140 includes a conductor portion 141 and a terminal portion 142. The terminal portion 142 includes a pair of terminals 142a and 142b. The conductor portion 141 is encapsulated inside the encapsulating portion 130 and, in a planar view, partially surrounds magnetoelectric conversion element 20a and magnetoelectric conversion element 20b, together with a part of the terminal portion 142. A measurement current flows through the terminal portion 142 and the conductor portion 141. The pair of terminals 142a and 142b are physically integrally structured with the conductor portion 141 and are exposed to the outside of the encapsulating portion 130. The lead frame 140 is an example of a first lead frame. Fabrication of the lead frame 140 does not require using a form in which a plurality of conductor portions 141 and a plurality of terminal portions 142 are linked together. The fabrication may use a form in which metal component parts are in individual pieces.

The lead frame 150 includes a holding portion 151 and a terminal portion 152. The terminal portion 152 includes a plurality of terminals 152a. The holding portion 151 is encapsulated inside the encapsulating portion 130 and holds a signal processing IC 100. The signal processing IC 100 may be fixed to a surface 151a of the holding portion 151 via an adhesive layer. The adhesive layer may be a die attach film.

When the lead frame 140 is configured with lead frames, so that the lead frame 140 and the lead frame 150 are arranged to overlap with each other in a thickness direction, at least one of the lead frame 140 or the lead frame 150 may be provided with a step in the thickness direction, in order to secure electrical insulation between the lead frame 140 and the lead frame 150 or the signal processing IC 100. For example, the holding portion 151 may include a stepped portion 155 that rises from the surface 151a supporting the signal processing IC 100 toward the conductor portion 141 side. The stepped portion 155 may be formed by the holding portion 151 recessing in the thickness direction (the z axis direction) in a direction away from the conductor portion 141 (toward a bottom face of the encapsulating portion 130). The stepped portion 155 may be formed by applying half blanking processing to the lead frame 150. Note that the stepped portion 155 does not need to be provided.

The plurality of terminals 152a are physically integrally structured with the holding portion 151 and are exposed to the outside of the encapsulating portion 130. The lead frame 150 is an example of a second lead frame. The lead frame 140 and the lead frame 150 may be configured by using a conductive material principally made of copper.

The x axis is a direction along the surfaces of the lead frame 140 and the lead frame 150 and is the direction along which the plurality of terminals 152a are arranged. The y axis is a direction along the surfaces of the lead frame 140 and the lead frame 150 and is the direction intersecting the x axis. The y axis is also a direction in which, in a planar view, the plurality of terminals 152a and the pair of terminals 142a and 142b extend. The z axis is a direction intersecting the surfaces of the lead frame 140 and the lead frame 150, is also a direction intersecting a circuit surface (a surface 100a) of the signal processing IC 100, and is also a thickness direction of the encapsulating portion 130.

The pair of terminals 142a, 142b and the plurality of terminals 152a are arranged to oppose each other via the signal processing IC 100, in a direction (the y axis direction) intersecting the thickness direction (the z axis direction) of the signal processing IC 100. The pair of terminals 142a and 142b are exposed from a side surface 130a of the encapsulating portion 130. The plurality of terminals 152a are exposed from a side surface 130b opposite from the side surface 130a of the encapsulating portion 130.

The pair of terminals 142a and 142b may have a part that is apart from the side surface 130a of the encapsulating portion 130 and is bent toward the bottom face 130f side of the encapsulating portion in the thickness direction. The plurality of terminals 152a may have a part that is apart from the side surface 130b of the encapsulating portion and is bent toward the bottom face 130f side of the encapsulating portion in the thickness direction. The bending direction of the pair of terminals 142a, 142b and the plurality of terminals 152a may be toward a ceiling face 130e side of the encapsulating portion, instead of toward the bottom face 130f side of the encapsulating portion 130 in the thickness direction.

The magnetoelectric conversion elements 20a, 20b are electrically connected to the signal processing IC 100 via a plurality of wires 22a, 22b. The magnetoelectric conversion elements 20a and 20b are configured separately from the signal processing IC 100, and output a signal processed by the signal processing IC 100 to the signal processing IC 100. The signal processing IC 100 is electrically connected to a plurality of terminals 152a via a wire 108. The wires 22a, 22b and the wire 108 may be formed by using a conductive material principally made of Au, Ag, Cu, or Al.

The magnetoelectric conversion elements 20a and 20b may protrude from the surface 100a of the signal processing IC 100 so that magnetic sensing surfaces of the magnetoelectric conversion elements 20a and 20b overlap with the conductor portion 141 in a side view. Accordingly, a sensitivity of each of the magnetoelectric conversion elements 20a and 20b can be increased.

The magnetoelectric conversion elements 20a and 20b detect magnetic fields in specific directions that change according to the measurement current flowing through the conductor portion 141, so that the signal processing IC 100 amplifies a signal corresponding to a magnitude of a magnetic field and outputs the amplified signal via the terminal 152a. The magnetoelectric conversion elements 20a and 20b include a compound semiconductor formed on a GaAs substrate and may be chips cut out in a square or rectangular shape in a planar view from the z axis direction.

The magnetoelectric conversion elements 20a and 20b may each have a substrate made of silicon or a compound semiconductor, and a magnetoelectric conversion unit provided on the substrate. The thickness of the substrate is adjusted by polishing a surface of the −z axis direction side. Since the detection is for a magnetic field in the z axis direction, horizontal Hall elements, for example, may be appropriate as the magnetoelectric conversion elements 20a and 20b. Also, when the magnetoelectric conversion elements 20a and 20b are arranged in positions to detect a magnetic field in the direction of any one of the axes on an xy plane, magnetoresistance elements or fluxgate elements may be appropriate as the magnetoelectric conversion elements 20a and 20b when being arranged, for example, in a position to detect a magnetic field in the x axis direction.

The magnetoresistance element may be, for example, a semiconductor magnetoresistance element (SMR), an anomalous magnetoresistance element (AMR), a giant magnetoresistance element (GMR), or a tunnel magnetoresistance element (TMR).

In the present embodiment, the magnetoelectric conversion elements 20a and 20b are not incorporated in the signal processing IC 100 and are installed on the circuit surface (the surface 100a). In other words, as for the current sensor 10, the magnetoelectric conversion elements 20a, 20b and the signal processing IC 100 are configured to be separate and do not have a monolithic structure. However, the magnetoelectric conversion elements 20a and 20b may be configured to have a monolithic structure while being incorporated in the signal processing IC 100. Also, in the present embodiment, an example will be described in which the current sensor 10 includes the two magnetoelectric conversion elements 20a and 20b. However, it is sufficient if the current sensor 10 includes one or more magnetoelectric conversion elements.

The signal processing IC 100 is a large-scale integrated circuit (LSI). The signal processing IC 100 is a signal processing circuit comprised of a Si monolithic semiconductor formed on an Si substrate. The signal processing circuit processes output signals corresponding to the magnitudes of the magnetic field output from the magnetoelectric conversion elements 20a and 20b. Based on the output signal, the signal processing circuit corrects the measurement current flowing through the conductor portion 141 and outputs an output signal representing a corrected current value via the terminal 152a. In other words, the signal processing IC 100 and the lead frame 150 are electrically connected via a wire or the like. The signal processing circuit reduces noise components included in an output signal of the magnetoelectric conversion element 20a and an output signal of the magnetoelectric conversion element 20b based on a difference between the output signal of the magnetoelectric conversion element 20a and the output signal of the magnetoelectric conversion element 20b, adds together and amplifies the output signal of the magnetoelectric conversion element 20a and the output signal of the magnetoelectric conversion element 20b of which the noise components have been reduced, calculates a current value of the measurement current based on the amplified output signal, and outputs an output signal representing the current value.

As illustrated in FIG. 1B, the pair of terminals 142a and 142b and the plurality of terminals 152a may protrude outward from heights, which are different in a thickness direction of the encapsulating portion 130, of the side surface 130a and the side surface 130b of the encapsulating portion 130, the side surface 130a and the side surface 130b facing each other. A height, from the bottom face (the surface 130f) of the encapsulating portion 130, of a part of the conductor portion 141 that does not overlap with the signal processing IC 100 in the thickness direction (the z axis direction) is different from a height of the holding portion 151 from the surface 130f of the encapsulating portion 130.

A height of a plane 1521 of the plurality of terminals 152a in the thickness direction (the z axis direction) of the encapsulating portion 130, at positions intersecting the side surface 130b of the encapsulating portion 130, on the same side as the surface 100a of the signal processing IC 100 may be equal to a height of a plane 1421 of the pair of terminals 142a and 142b in the thickness direction (the z axis direction) of the encapsulating portion 130, at positions intersecting the side surface 130a of the encapsulating portion 130, on the same side as the surface opposite from the surface 100a of the signal processing IC 100. Alternatively, the height of the plane 1521 of the plurality of terminals 152a in the thickness direction (the z axis direction) of the encapsulating portion 130, at the positions intersecting the side surface 130b of the encapsulating portion 130 may be positioned lower than the height of the plane 1421 of the pair of terminals 142a and 142b in the thickness direction (the z axis direction) of the encapsulating portion 130, at the positions intersecting the side surface 130a of the encapsulating portion 130.

In the current sensor in FIG. 1B, the height of the plane 1521 of the plurality of terminals 152a in the thickness direction (the z axis direction) of the encapsulating portion 130, at the positions intersecting the side surface 130b of the encapsulating portion 130 is positioned lower than the height of the plane 1421 of the pair of terminals 142a and 142b in the thickness direction (the z axis direction) of the encapsulating portion 130, at the positions intersecting the side surface 130a of the encapsulating portion 130.

The pair of terminals 142a and 142b protrude from the side surface 130a toward the negative side in the y axis direction and are further bent toward the negative side in the x axis direction. The plurality of terminals 152a protrude from the side surface 130b toward the positive side in the y axis direction and are further bent toward the negative side in the z axis direction. The pair of terminals 142a and 142b may protrude from the side surface 130a toward the negative side in the y axis direction and may further be bent toward the positive side in the z axis direction. The plurality of terminals 152a may protrude from the side surface 130b toward the positive side in the y axis direction and may further be bent toward the positive side in the z axis direction. The pair of terminals 142a and 142b and the plurality of terminals 152a do not need to be bent. In other words, the pair of terminals 142a and 142b may protrude from the side surface 130a toward the negative side in the y axis direction, without being bent toward either of the positive and the negative sides in the z axis direction. The plurality of terminals 152a may protrude from the side surface 130b toward the positive side in the y axis direction, without being further bent toward either of the positive and the negative sides in the Z axis direction.

The lead frame 140 includes a slit portion 1411 extending in the y axis direction and a slit portion 1412 extending in the x axis direction in a planar view. The two slit portions 1411 and 1412 are provided for the conductor portion 141 and are encapsulated inside the encapsulating portion 130. As being arranged in the slit portion 1411, the magnetoelectric conversion element 20a is partially surrounded by the lead frame 140, in a planar view. Also, as being arranged in the slit portion 1412, the magnetoelectric conversion element 20b is partially surrounded by the lead frame 140, in a planar view.

As a result of the magnetoelectric conversion element 20a being arranged in the slit portion 1411, three side surfaces of the magnetoelectric conversion element 20a may be surrounded by the lead frame 140. In this manner, because a measured current is not branched, a high current density is achieved in a part of the lead frame 140 positioned close to the magnetoelectric conversion element 20a. As a result, it is possible to further increase sensitivity. As a result of the magnetoelectric conversion element 20b being arranged in the slit portion 1412, three side surfaces of the magnetoelectric conversion element 20b may be surrounded by the lead frame 140.

The magnetoelectric conversion elements 20a and 20b may be fixed to the circuit surface of the signal processing IC 100 by die bonding and electrically connected to the signal processing IC 100 by wire bonding. That is, the magnetoelectric conversion elements 20a and 20b may be electrically connected to the signal processing IC 100 via a plurality of wires 22a and 22b. The plurality of wires 22a and 22b may be electrically connected to the magnetoelectric conversion elements 20a and 20b and the signal processing IC 100 in the slit portions 1411 and 1412. In other words, the plurality of wires 22a and 22b may electrically connect the magnetoelectric conversion elements 20a and 20b and the signal processing IC 100, without straddling the lead frame 140. In this way, a magnetic flux linked with the wire can be reduced, an induced electromotive force is less likely to be generated, and it becomes easier to respond quickly.

The magnetoelectric conversion elements 20a and 20b may be electrically connected to the signal processing IC 100 by flip chip bonding. The magnetoelectric conversion elements 20a and 20b output, to the signal processing IC 100, signals to be processed by the signal processing IC 100. The magnetoelectric conversion elements 20a and 20b may be configured separately from the signal processing IC 100. That is, the magnetoelectric conversion elements 20a and 20b may be constituted by chips different from chips constituting the signal processing IC 100. The magnetoelectric conversion elements 20a and 20b may be incorporated in the chips constituting the signal processing IC 100.

The encapsulating portion 130 encapsulates, by using mold resin, the magnetoelectric conversion element 20a and 20b, the conductor portion 141 of the lead frame 140, the holding portion 151 of the lead frame 150, the signal processing IC 100, the wires 22, and the wire 108. The mold resin may be, for example, comprised of an epoxy-based thermosetting resin added with silica and formed into a semiconductor package by a transfer molding.

FIG. 1C shows a first variation of the interior configuration of the semiconductor package that functions as the current sensor 10 according to the present embodiment. Similarly to FIG. 1B, FIG. 1C is an A-A line sectional view of the current sensor 10 shown in FIG. 1A.

FIG. 1D shows a second variation of the interior configuration of the semiconductor package that functions as the current sensor 10 according to the present embodiment. Similarly to FIG. 1B, FIG. 1D is an A-A line sectional view of the current sensor 10 shown in FIG. 1A.

FIG. 1E shows a third variation of the interior configuration of the semiconductor package that functions as the current sensor 10 according to the present embodiment. Similarly to FIG. 1B, FIG. 1E is an A-A line sectional view of the current sensor 10 shown in FIG. 1A.

The current sensors 10 of the first variation and the second variation are different from the current sensor 10 according to the present embodiment shown in FIG. 1B in that the height of the plane 1521 of the plurality of terminals 152a in the thickness direction (the z axis direction) of the encapsulating portion 130, at the positions intersecting the side surface 130b of the encapsulating portion 130, on the same side as the surface 100a of the signal processing IC 100 is equal to the height of the plane 1421 of the pair of terminals 142a and 142b (the terminal portion 142) in the thickness direction (the Z axis direction) of the encapsulating portion 130, at the positions intersecting the side surface 130a of the encapsulating portion 130, on the same side as the surface opposite from the surface 100a of the signal processing IC 100.

In the current sensor 10 of the first variation, the conductor portion 141 of the lead frame 140 is provided with a stepped portion 1413, while the conductor portion 141 has a part 1414 positioned on the bottom face 130f side of the encapsulating portion 130 and a part 1415 positioned on the ceiling face 130e side of the encapsulating portion 130 which are contiguous via the stepped portion 1413. The part 1414 is also contiguous with the terminal portion 142. The stepped portion 1413 may be formed by applying half blanking processing to the lead frame 140.

Compared to the current sensor 10 according to the present embodiment shown in FIG. 1B, in the current sensor 10 of the second variation, the encapsulating portion 130 is thicker, and the recess of the holding portion 151 is larger.

In the current sensor 10 of the first variation and the current sensor 10 of the second variation having the configurations described above, it is possible to make the height of the plane 1521 of the plurality of terminals 152a in the thickness direction (the z axis direction) of the encapsulating portion 130, at the positions intersecting the side surface 130b of the encapsulating portion 130, on the same side as the surface 100a of the signal processing IC 100 equal to the height of the plane 1421 of the pair of terminals 142a and 142b (the terminal portion 142) in the thickness direction (the Z axis direction) of the encapsulating portion 130, at the positions intersecting the side surface 130a of the encapsulating portion 130, on the same side as the surface opposite from the surface 100a of the signal processing IC 100, while keeping the distance between the lead frame 140 and the lead frame 150 and the signal processing IC 100; however, possible means for making the heights equal to each other are not limited to this.

The current sensor 10 of the third variation is different from the current sensor 10 of the second variation shown in FIG. 1B in that the conductor portion 141 of the lead frame 140 is provided with a stepped portion 1416, while the conductor portion 141 has a part 1417 positioned on the ceiling face 130e side of the encapsulating portion 130 and a part 1418 positioned on the bottom face 130f side of the encapsulating portion 130 which are contiguous via the stepped portion 1416. The part 1417 is also contiguous with the terminal portion 142. The stepped portion 1416 may be formed by applying half blanking processing to the lead frame 140.

In the current sensor 10 of the third variation, the height of the plane 1521 of the plurality of terminals 152a in the thickness direction (the z axis direction) of the encapsulating portion 130, at the positions intersecting the side surface 130b of the encapsulating portion 130 is positioned lower than the height of the plane 1421 of the pair of terminals 142a and 142b in the thickness direction (the z axis direction) of the encapsulating portion 130, at the positions intersecting the side surface 130a of the encapsulating portion 130. The height of the plane 1521 of the plurality of terminals 152a in the thickness direction (the z axis direction) of the encapsulating portion 130, at the positions intersecting the side surface 130b of the encapsulating portion 130 is equal to the height of the plane of the part 1418 of the conductor portion 141 facing the signal processing IC 100 in the thickness direction (the z axis direction) of the encapsulating portion 130.

By having a height difference between the part 1417 and the part 1418, the current sensor 10 of the third variation is able to easily let the electric field inside the semiconductor package escape and to inhibit the partial discharge, and is thus more preferable.

FIG. 1F and FIG. 1G show a variation of a semiconductor package that functions as a fourth variation of the current sensor 10 according to the present embodiment. FIG. 1F is a schematic plan view of the current sensor 10 according to the fourth variation as seen from the ceiling face side (the z axis direction). FIG. 1G is an A-A line sectional view of the current sensor 10 shown in FIG. 1F.

The current sensor 10 of the fourth variation is different from the current sensors 10 shown in FIG. 1A and FIG. 1B in that the lead frame 150 does not include the holding portion 151; a surface 141b of the conductor portion 141 of the lead frame 140 is adhered to the surface 100a of the signal processing IC 100 via an insulation tape 30; and the signal processing IC 100 is held by the lead frame 140.

In the current sensor 10 of the fourth variation, the magnetoelectric conversion elements 20a and 20b may be configured to have a monolithic structure integrated with the signal processing IC 100. The magnetoelectric conversion elements 20a and 20b may be provided on the ceiling face 130e side of the encapsulating portion 130.

Further, the parameters T_{ds}, T_{b}, and Tₜ presented in FIG. 1B to FIG. 1E and FIG. 1G are defined as follows:
T_{ds}: the shortest distance among distances from the surface 130a of the encapsulating portion 130 to the lead frame 150 or to the signal processing IC 100;
T_{b}: the distance between the surface 130f of the encapsulating portion 130 and, of a surface 100b of the signal processing IC 100 or a surface 151b of a conductor portion 150, a part closest to the surface 130a of the encapsulating portion 130; and
Tₜ: the distance between a part of the surface 141a of the conductor portion 141 that is closest to the surface 130b of the encapsulating portion 130 and the surface 130e of the encapsulating portion 130 facing the surface 141a of the conductor portion 141.

That is, in FIG. 1B to FIG. 1E, T_{ds} denotes the shortest distance between the surface 130a of the encapsulating portion 130 and the holding portion 151. In FIG. 1G, T_{ds} denotes the shortest distance between the surface 130a of the encapsulating portion 130 and the signal processing IC 100. In FIG. 1B to FIG. 1E, T_{b} denotes the distance between the surface 130f of the encapsulating portion 130 and the surface 151b of the holding portion 151. In FIG. 1G, T_{b} denotes the distance between the surface 130f of the encapsulating portion 130 and the surface 100b of the signal processing IC 100. Also, even when a current sensor includes the holding portion 151, if the signal processing IC 100 is structured to protrude toward the surface 130a side of the encapsulating portion 130 relative to the holding portion 151, T_{b} denotes the distance between the surface 130f of the encapsulating portion 130 and the surface 100b of the signal processing IC 100.

In the current sensor 10 configured in this manner, it is desired to secure with higher certainty an insulation performance when a great current flows in or high voltage is applied to the conductor portion 141. In addition, in order to enable a further greater current to flow through the conductor portion 141, it is also required to suppress heat generation of the conductor portion 141 caused by the current flowing through the conductor portion 141. By lowering resistance of the conductor portion 141, it is possible to suppress the heat generation of the conductor portion 141. It is possible to realize the lowering of the resistance of the conductor portion 141, by making the conductor portion 141 thicker and shorter.

However, when the conductor portion 141 is made thicker, there is a chance that the distance between the conductor portion 141 and the surface of the encapsulating portion 130 may be shorter. In this case, applying high voltage to the conductor portion 141 allows an electric field concentration to easily occur on the surface of the encapsulating portion 130, and there is a chance that a creepage discharge might be induced on a surface of the encapsulating portion 130 due to a potential difference between the lead frame 140 on the current conductor side and the surroundings. Accordingly, it would not be easy to design the current sensor 10 so as to enable a great current to flow through the conductor portion 141 of the current sensor 10 while also securing an insulation performance.

Thus, the present embodiment provides a current sensor 10 capable of enabling a great current to flow while also securing an insulation performance.

In order to realize such a current sensor 10, the present embodiment refers to a Darkin's equation, which is empirically known as equations for predicting partial discharge start voltage. A Darkin's equation can be expressed as Expression 1.

$$V p = 163 {( t / {ε}_{r} )}^{0.46} \qquad ( 1 )$$

Vp denotes partial discharge start voltage (V); εᵣ denotes a relative permittivity of an insulating layer; and t denotes a thickness (μm) of the insulating layer.

The higher the partial discharge start voltage Vp is, the smaller is the electric field E on a surface of the package (the encapsulating portion 130) when constant voltage V is applied. Thus, the partial discharge start voltage Vp and the electric field E are in a relationship of reciprocals. That is, the partial discharge start voltage Vp and the electric field E are in a relationship of an inverse proportion and has a relationship of E=C′×V/Vp where a constant C′ is used. Thus, in consideration of E=C′×V/Vp and Expression 1, it is possible to express a maximum value Emax of an electric field in a specific region on a surface of a package when constant voltage V is applied, by using Expression 2.

$$E max = C \times {T}_{ds}^{x} \times {ε}^{y} \times V \qquad ( 2 )$$

The specific region on the surface of a package may arbitrarily be determined in accordance with a location where a partial discharge from the surface needs to be considered.

In the present example, C, x, and y are constants; T_{ds} denotes the thickness of the encapsulating portion 130 on a side surface; and ε denotes a relative permittivity of the mold resin structuring the package. The thickness of the encapsulating portion 130 on a side surface is the shortest distance among distances from the side surface 130a of the encapsulating portion 130 exposing the terminal portion 142 on the current conductor side, to the holding portion 151 or to the signal processing IC 100.

In this situation, because Emax (V/m) is proportional to V (V) based on Expression 2, it is conjectured that a condition under which no creepage discharge occurs with specific voltage V₀ (V) is determined by the value of C×T_{ds}^{x}×ε^{y}. V₀ (V) may arbitrarily be determined according to purposes of use or the like.

In the present embodiment, the value of C×T_{ds}^{x}×ε^{y} being smaller than 400 is regarded as a condition under which there is a high possibility that no creepage discharge occurs on a surface of the encapsulating portion 130. In other words, it is acceptable when a maximum value of an electric field in a specific region on the package surface while V=1 (V) is smaller than 400 (V/m).

By setting various conditions of T_{ds} and ε while using Expression 2 for the current sensor shown in FIG. 1C, the electric field E on the surface of the package was calculated by using the finite element method, so as to derive optimal C, x, and y. As a result, it was discovered that approximation was possible with C=523, x=−1, and y=0.08.

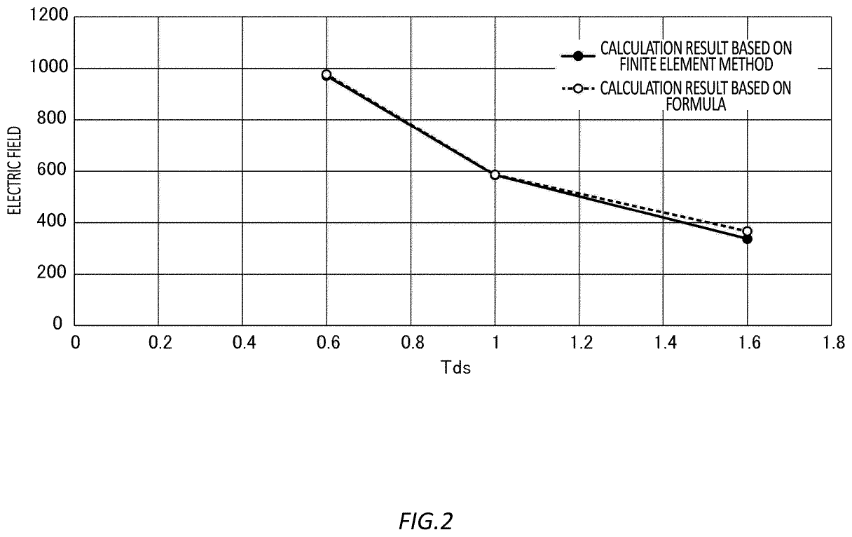

FIG. 2 shows, regarding the current sensor shown in FIG. 1C, a result based on Expression 2 representing a relationship between the maximum value Emax of an electric field and T_{ds}, when voltage of 1 (V) is applied to a current conductor on a surface (the side surface 130a) of the encapsulating portion 130, while C=523, x=−1, and y=0.08, and a result based on the finite element method. As shown in FIG. 2, while C=523, x=−1, and y=0.08, the result based on Expression 2 was a result matching the result based on the finite element method.

In other words, in the present embodiment, when T_{ds} denotes the shortest distance among distances from the side surface 130a of the encapsulating portion 130 exposing the terminal portion 142 on the current conductor side to the holding portion 151 or to the signal processing IC 100, and ε denotes the relative permittivity of the mold resin, it is possible to prevent the creepage discharge on the surface (the surface 130a) of the encapsulating portion 130, by designing the shortest distance T_{ds} among the distances from the side surface 130a of the encapsulating portion 130 to the holding portion 151 or to the signal processing IC 100 and the relative permittivity ε of the mold resin so as to satisfy 523×T_{ds}⁻¹×ε^{0.08}<400 (V/m).

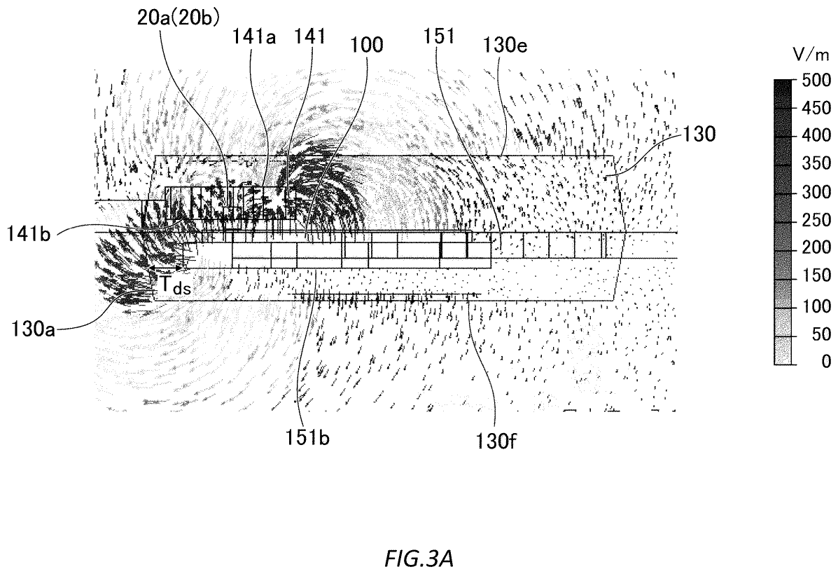

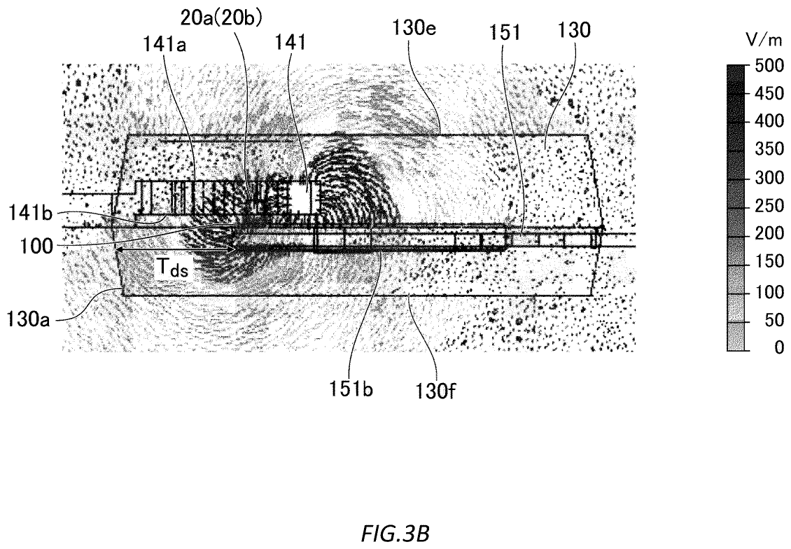

FIG. 3A shows a distribution of magnitudes of the electric field E generated by a potential difference occurring in the surroundings of the conductor portion 141 when voltage of 1 (V) is applied to the current conductor in the current sensor shown in FIG. 1C, while T_{ds}=0.6 mm. FIG. 3B shows a distribution of magnitudes of the electric field E generated by a partial discharge occurring between the holding portion 151 and the conductor portion 141, when voltage of 1 (V) is applied to the current conductor in the current sensor shown in FIG. 1C, while T_{ds}=1.6 mm. As shown in FIG. 3A, when T_{ds}=0.6 mm, a region having a strong electric field where E is 400 (V/m) or larger spreads even to the outside of the surface of the encapsulating portion 130. In contrast, as shown in FIG. 3B, when T_{ds}=1.6, a region having a strong electric field where E is 400 (V/m) or larger is contained in the encapsulating portion 130.

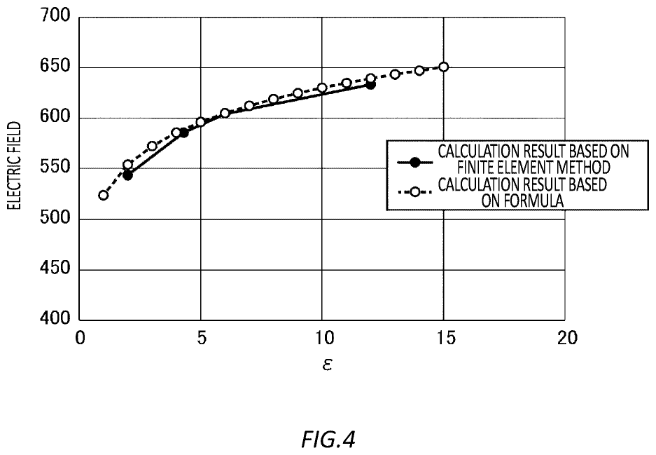

FIG. 4 shows, regarding the current sensor shown in FIG. 1C, a result based on Expression 2 representing a relationship between the electric field E and the relative permittivity ε, when voltage of 1 (V) is applied to a current conductor on a surface (the side surface 130a) of the encapsulating portion 130, while C=523, x=−1, y=0.08, and T_{ds}=0.6, and a result based on the finite element method. When T_{ds}=0.6, even if the relative permittivity ε is made small, the electric field does not become smaller than 400 (V/m). In other words, when T_{ds} is too small, it is not possible to inhibit the creepage discharge on the surface of the encapsulating portion 130. Accordingly, in consideration of the result in FIG. 2, in order to ensure that no creepage discharge occurs on the surface of the encapsulating portion 130, it is desirable that T_{ds} is 1.5 mm or longer, and preferably 2.0 mm or longer.

Next, with reference to a Darkin's equation, it is possible to express the maximum value Emax of an electric field in a specific region on a surface of a package when constant voltage V is applied by using Expression 3, where V denotes partial discharge start voltage; T_{b} denotes the distance between the surface 130f of the encapsulating portion 130 and, of the surface 100b of the signal processing IC 100 or the surface 151b of the conductor portion 150, a part closest to the surface 130a of the encapsulating portion 130; ε denotes the relative permittivity of the mold resin; and C, x, and y are constants.

$$E max = C \times {T}_{b}^{x} \times {ε}^{y} \times V \qquad ( 3 )$$

In this situation, because Emax (V/m) is proportional to V (V) based on Expression 3, it is conjectured that a condition under which no creepage discharge occurs with specific voltage V₀ (V) is determined by the value of C×T_{b}^{x}×ε^{y}. V₀ (V) may arbitrarily be determined according to purposes of use or the like.

In the present embodiment, the value of C×T_{b}^{x}×ε^{y} being smaller than 400 is regarded as a condition under which there is a high possibility that no creepage discharge occurs on a surface of the encapsulating portion 130. In other words, it is acceptable when a maximum value of an electric field in a specific region on the package surface while V=1 (V) is smaller than 400 (V/m).

By setting various conditions of T_{b} and ε while using Expression 3 for the current sensor shown in FIG. 1D, the electric field E on the surface of the package (the encapsulating portion 130) was calculated by using the finite element method, so as to derive optimal C, x, and y. As a result, it was discovered that approximation was possible with C=470, x=−1, and y=0.08.

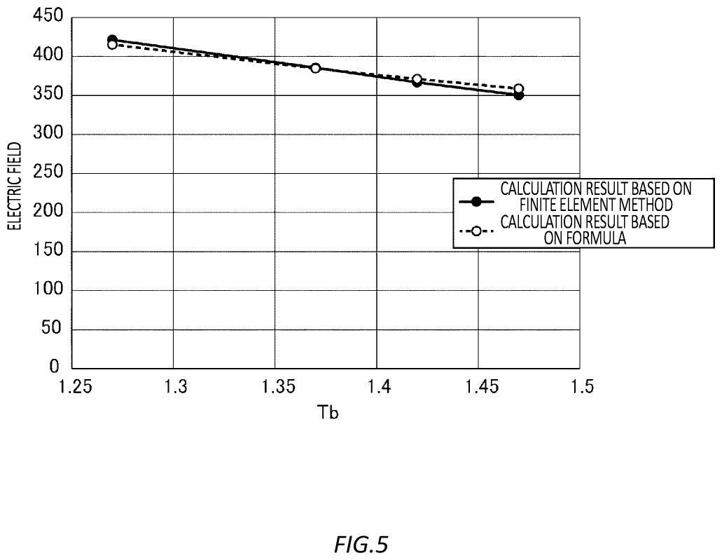

FIG. 5 shows, regarding the current sensor shown in FIG. 1D, a result based on Expression 3 representing a relationship between the maximum value Emax of an electric field and T_{b}, when voltage of 1 (V) is applied to a current conductor on a surface (the surface 130f) of the encapsulating portion 130, while C=470, x=−1, and y=0.08, and a result based on the finite element method. As shown in FIG. 5, while C=470, x=−1, and y=0.08, the result based on Expression 3 was a result matching the result based on the finite element method.

In other words, in the present embodiment, when T_{b} denotes the distance between the surface 100b of the signal processing IC 100 and the surface 130f of the encapsulating portion 130, and ε denotes the relative permittivity of the mold resin, it is possible to prevent the creepage discharge on the surface (the surface 130f) of the encapsulating portion 130, by designing the distance T_{b} between the surface 100b of the signal processing IC 100 and the surface 130f of the encapsulating portion 130 and the relative permittivity ε of the mold resin so as to satisfy 470×T_{b}⁻¹×ε^{0.08}<400 (V/m).

In consideration of the result shown in FIG. 5, it is understood that, when T_{b} is 1.35 mm or longer, the electric field E on the surface of the encapsulating portion 130 is not a strong electric field of 400 (V/m) or more. Accordingly, it is possible to conjecture from FIG. 5 that, in order for the electric field E on the surface (the surface 130f) of the encapsulating portion 130 to satisfy being smaller than 400 (V/m), it is acceptable when T_{b} is 1.35 mm or longer.

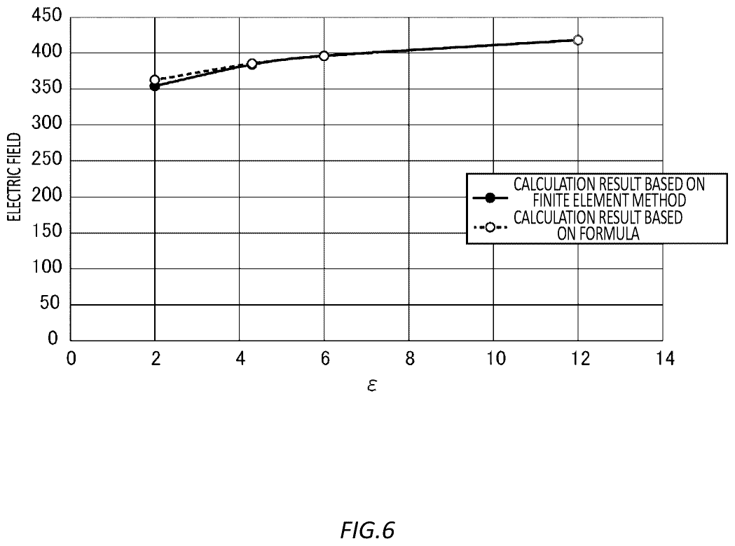

FIG. 6 shows, regarding the current sensor shown in FIG. 1D, a result based on Expression 3 representing a relationship between the electric field E and the relative permittivity ε, when voltage of 1 (V) is applied to a current conductor on a surface (the surface 130f) of the encapsulating portion 130, while C=470, x=−1, y=0.08, and T_{b}=1.37 mm, and a result based on the finite element method.

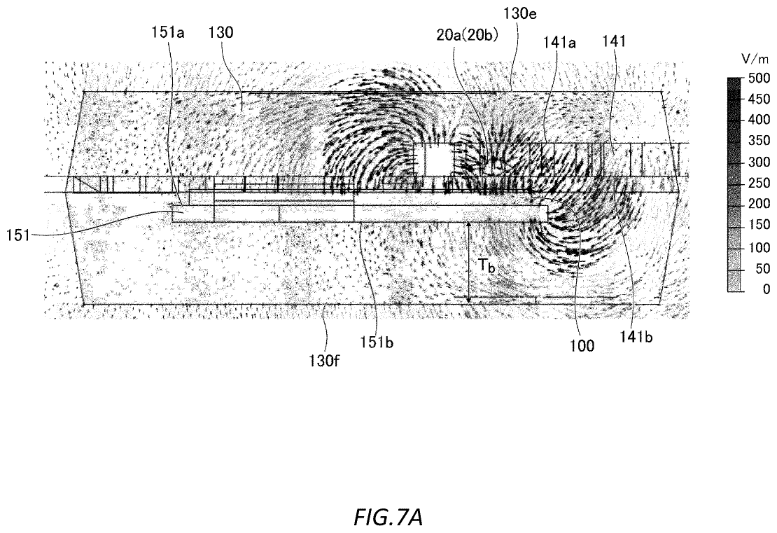

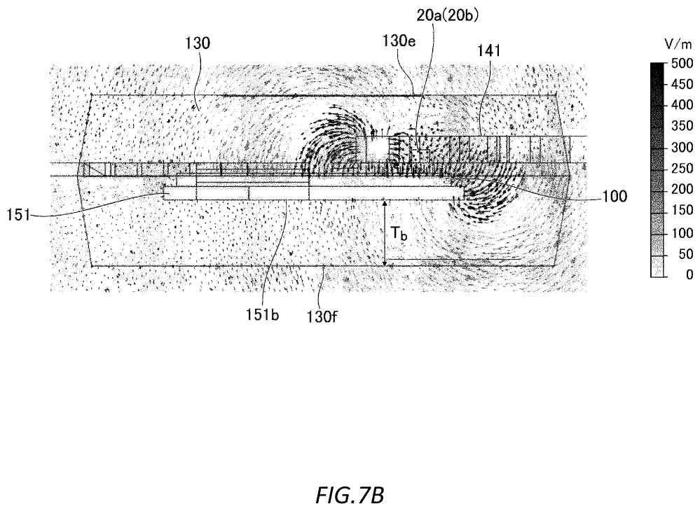

FIG. 7A shows a distribution of magnitudes of the electric field generated by a potential difference occurring in the surroundings of the conductor portion 141 when voltage of 1 (V) is applied to the current conductor in the current sensor shown in FIG. 1D, when ε=12, while C=470, x=−1, y=0.08, and T_{b}=1.37 mm. FIG. 7B shows a distribution of magnitudes of the electric field generated by a potential difference occurring between the holding portion 151 and the conductor portion 141, when voltage of 1 (V) is applied to the current conductor in the current sensor shown in FIG. 1D, when ε=2, while C=470, x=−1, y=0.08, and T_{b}=1.37 mm. As shown in FIG. 7A, when ε=12, a region having a strong electric field where E is 400 (V/m) or larger spreads even to the outside of the surface of the encapsulating portion 130. In contrast, as shown in FIG. 7B, when ε=2, a region having a strong electric field where E is 400 (V/m) or larger is contained in the encapsulating portion 130.

Further, with reference to a Darkin's equation, it is possible to express the maximum value Emax of an electric field in a specific region on a surface of a package when constant voltage V is applied by using Expression 4, where V denotes partial discharge start voltage; Tₜ denotes the distance between the surface 141a of the conductor portion 141 and the facing surface 130e of the encapsulating portion 130; ε denotes the relative permittivity of the mold resin; and C, x, and y are constants.

$$E max = C \times {T}_{t}^{x} \times {ε}^{u} \times V \qquad ( 4 )$$

In this situation, because Emax (V/m) is proportional to V (V) based on Expression 3, it is conjectured that a condition under which no creepage discharge occurs with specific voltage V₀ (V) is determined by the value of C×Tₜ^{x}×ε^{y}. V₀ (V) may arbitrarily be determined according to purposes of use or the like.

In the present embodiment, the value of C×Tₜ^{x}×ε^{y} being smaller than 400 is regarded as a condition under which there is a high possibility that no creepage discharge occurs on a surface of the encapsulating portion 130. In other words, it is acceptable when a maximum value of an electric field in a specific region on the package surface while V=1 (V) is smaller than 400 (V/m).

By setting various conditions of Tₜ and ε while using Expression 4 for the current sensor shown in FIG. 1D, the electric field E on the surface of the package was calculated by using the finite element method, so as to derive optimal C, x, and y. As a result, it was discovered that C=280, x=−0.2, and y=0.12 were optimal.

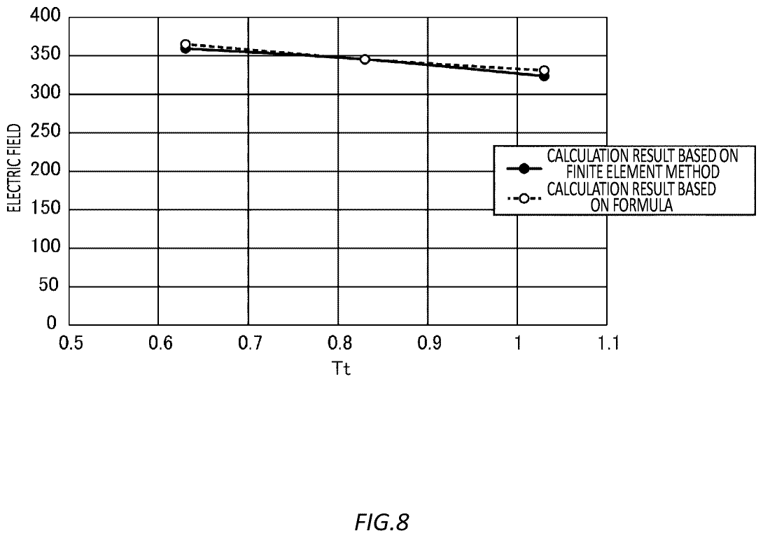

FIG. 8 shows, regarding the current sensor shown in FIG. 1D, a result based on Expression 4 representing a relationship between the maximum value Emax of an electric field and Tₜ, when voltage of 1 (V) is applied to a current conductor on a surface (the surface 130e) of the encapsulating portion 130, while C=280, x=−0.2, and y=0.12, and a result based on the finite element method. As shown in FIG. 8, while C=280, x=−0.2, and y=0.12, the result based on Expression 4 was a result matching the result based on the finite element method.

In other words, in the present embodiment, when Tₜ denotes the distance between the surface 141a of the conductor portion 141 and the facing surface 130e of the encapsulating portion 130, and ε denotes the relative permittivity of the mold resin, it is possible to prevent the creepage discharge on the surface (the surface 130e) of the encapsulating portion 130, by designing the distance Tₜ between the surface 141a of the conductor portion 141 and the facing surface 130e of the encapsulating portion 130 and the relative permittivity ε of the mold resin so as to satisfy 280×Tₜ^{-0.2}×ε^{0.12}<400 (V/m).

As shown in FIG. 8, when Tₜ is substantially 0.5 mm or longer, and preferably 0.6 mm or longer, it is possible to keep the electric field E on the surface (the surface 130e) of the encapsulating portion 130 smaller than 400 (V/m).

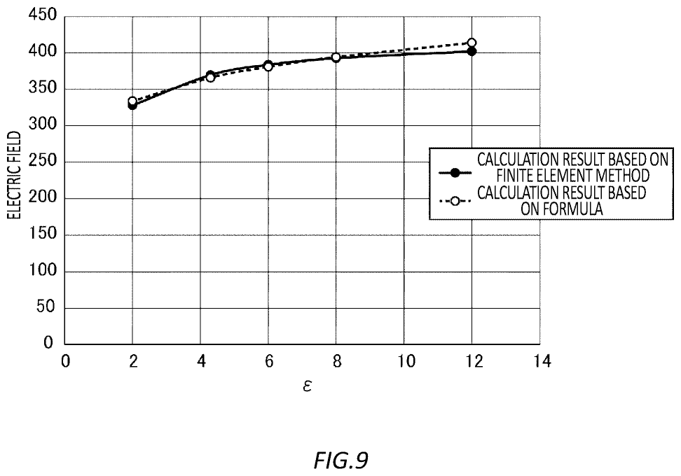

FIG. 9 shows, regarding the current sensor shown in FIG. 1D, a result based on Expression 4 representing a relationship between the electric field E and the relative permittivity ε, when voltage of 1 (V) is applied to a current conductor on a surface (the surface 130e) of the encapsulating portion 130, while C=280, x=−0.2, y=0.12, and Tₜ=0.63 mm, and a result based on the finite element method. When Tₜ=0.63 mm, if the relative permittivity ε is 8 or smaller and preferably 6 or smaller, it is possible to keep the electric field E on the surface (the surface 130e) of the encapsulating portion 130 smaller than 400 (V/m) and to thus prevent the creepage discharge on the surface of the encapsulating portion 130.

In consideration of the above, in order to prevent the creepage discharge on each of the surfaces of the encapsulating portion 130 such as the side surface 130a, the surface 130e, and the surface 130f, it is desirable to design the current sensor 10 so as to satisfy each of the following conditions where T_{ds} denotes the shortest distance among distances from the side surface 130a of the encapsulating portion 130 exposing the terminal portion 142 on the current conductor side to the holding portion 151 or to the signal processing IC 100; T_{b} denotes the distance between the surface 130f of the encapsulating portion 130 and, of the surface 100b of the signal processing IC 100 or the surface 151b of the conductor portion 150, a part closest to the surface 130a of the encapsulating portion 130; Tₜ denotes the distance between the surface 141a of the conductor portion 141 and the facing surface 130e of the encapsulating portion 130; and ε denotes the relative permittivity of the mold resin:

$$523 \times {T}_{ds}^{- 1} \times {ε}^{0.08} < 400 ( V / m ) ;$$

$$470 \times {T}_{b}^{- 1} \times {ε}^{0.08} < 400 ( V / m ) ; and$$

$$280 \times {T}_{t}^{- 0.2} \times {ε}^{0.12} < 400 ( V / m ) .$$

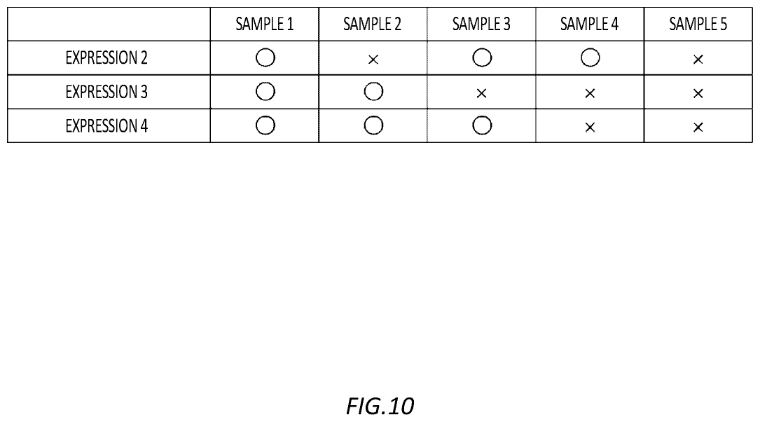

FIG. 10 is a condition table of samples created as examples. In relation to Expression 2, Expression 3, and Expression 4 presented below, ◯ indicates that the formula is satisfied, and x indicates that the formula is not satisfied:

$$\begin{matrix}Expression 2 : 523 \times {T}_{ds}^{- 1} \times {ε}^{0.08} < 400 ( V / m ) ; \\ Expression 3 : 470 \times {T}_{b}^{- 1} \times {ε}^{0.08} < 400 ( V / m ) ; and \\ Expression 4 : 280 \times {T}_{t}^{- 0.2} \times {ε}^{0.12} < 400 ( V / m ) .\end{matrix}$$

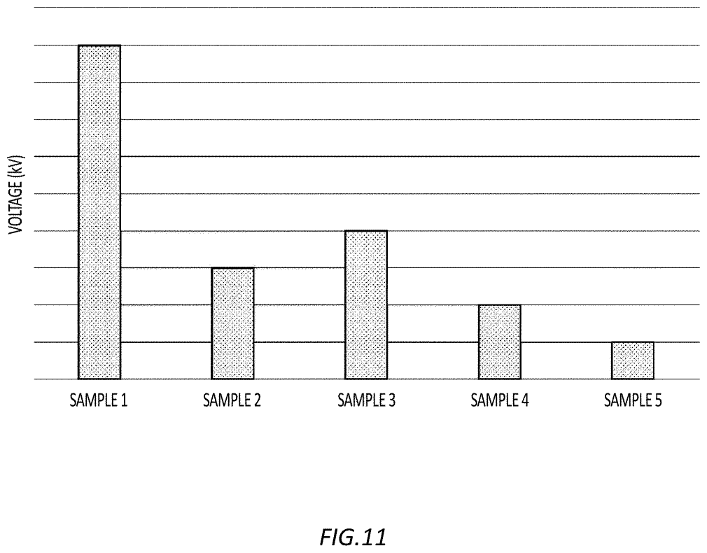

FIG. 11 is a drawing showing creepage discharge generated voltage of each of the samples with respect to Expression 2, Expression 3, and Expression 4. As shown in FIG. 11, higher creepage discharge inhibiting effects were confirmed when one or two of Expressions 2, 3, and 4 were satisfied like in Samples 2, 3, and 4, as compared to when none of Expressions 2, 3, and 4 was satisfied like in Sample 5. Further, when Expressions 2, 3, and 4 were all satisfied like in Sample 1, a great creepage discharge preventing effect was achieved. Note that which one of Expressions 2, 3, and 4 exhibits the highest effect depends on PKG internal structures.

While the present invention has been described above by way of the embodiments, the technical scope of the present invention is not limited to the scope described in the above-described embodiments. It is apparent to persons skilled in the art that various alterations or improvements can be made to the above-described embodiments. It is also apparent from the description of the claims that the form to which such alterations or improvements are made can be included in the technical scope of the present invention.

It should be noted that the operations, procedures, steps, stages, etc. of each process performed by a device, system, program, and method shown in the claims, specification, or diagrams can be performed in any order as long as the order is not indicated by “prior to,” “before,” or the like and as long as the output from a previous process is not used in a later process. Even if the operational flow is described by using phrases such as “first” or “next” in the claims, specification, or diagrams, it does not necessarily mean that the process must be performed in this order.

### Item 1

A current sensor comprising:
at least one magnetoelectric conversion unit;
a first lead frame which includes a first terminal portion and a conductor portion coupled with the first terminal portion and through which a measurement current measured by the at least one magnetoelectric conversion unit flows via the first terminal portion and the conductor portion;
a signal processing IC which is arranged on a second surface side opposite from a first surface of the conductor portion and has a circuit surface on which the at least one magnetoelectric conversion unit is arranged, the signal processing IC processing a signal output from the at least one magnetoelectric conversion unit;
a second lead frame including a second terminal portion which outputs a signal from the signal processing IC; and
an encapsulating portion which encapsulates, by using mold resin, the at least one magnetoelectric conversion unit, the conductor portion, the signal processing IC, and a part of the second lead frame, wherein

$$523 \times {T}_{ds}^{- 1} \times {ε}^{0.08} < 400$$

is satisfied where T_{ds} denotes a shortest distance among distances from a first side surface of the encapsulating portion exposing the first terminal portion to the second lead frame or to the signal processing IC; and ε denotes a relative permittivity of the mold resin.

### Item 2

The current sensor according to Item 1, wherein T_{ds} is 1.6 mm or longer.

### Item 3

The current sensor according to Item 1, wherein
regarding the signal processing IC, a surface on the second surface side of the conductor portion is a first surface of the signal processing IC, and a surface on an opposite side from the first surface of the signal processing IC is a second surface, and
the second lead frame has, on the second surface side of the signal processing IC, a holding portion which holds the signal processing IC.

### Item 4

The current sensor according to Item 3, wherein the shortest distance T_{ds} is a distance between the first side surface of the encapsulating portion and the holding portion.

### Item 5

A current sensor comprising:
at least one magnetoelectric conversion unit;
a first lead frame which includes a first terminal portion and a conductor portion coupled with the first terminal portion and through which a measurement current measured by the at least one magnetoelectric conversion unit flows via the first terminal portion and the conductor portion;
a signal processing IC which is arranged on a second surface side opposite from a first surface of the conductor portion and has a circuit surface on which the at least one magnetoelectric conversion unit is arranged, the signal processing IC processing a signal output from the at least one magnetoelectric conversion unit;
a second lead frame including a second terminal portion which outputs a signal from the signal processing IC; and
an encapsulating portion which encapsulates, by using mold resin, the at least one magnetoelectric conversion unit, the conductor portion, the signal processing IC, and a part of the second lead frame, wherein
regarding the signal processing IC, a surface on the second surface side of the conductor portion is a first surface of the signal processing IC, and a surface on an opposite side from the first surface of the signal processing IC is a second surface,
regarding the encapsulating portion, a surface facing the first surface of the conductor portion is a first surface of the encapsulating portion, a surface facing the second surface of the conductor portion is a second surface of the encapsulating portion, and a surface of the conductor portion exposing the first terminal portion is a first side surface, and

$$470 \times {T}_{b}^{- 1} \times {ε}^{0.08} < 400$$

is satisfied where T_{b} denotes a distance between the second surface of the encapsulating portion and, of the second surface of the signal processing IC or the second surface of the conductor portion, a part closest to the first side surface of the encapsulating portion; and ε denotes a relative permittivity of the mold resin.

### Item 6

The current sensor according to Item 5, wherein T_{b} is 1.35 mm or longer.

### Item 7

The current sensor according to Item 5, wherein
regarding the signal processing IC, the surface on the second surface side of the conductor portion is the first surface of the signal processing IC, and the surface on the opposite side from the first surface of the signal processing IC is the second surface, and
the second lead frame has, on the second surface side of the signal processing IC, a holding portion which holds the signal processing IC.

### Item 8

The current sensor according to Item 7, wherein a height, from the second surface of the encapsulating portion, of a part of the conductor portion that does not overlap with the signal processing IC in a thickness direction is different from a height of the holding portion from the second surface of the encapsulating portion.

### Item 9

A current sensor comprising:
at least one magnetoelectric conversion unit;
a first lead frame which includes a first terminal portion and a conductor portion coupled with the first terminal portion and through which a measurement current measured by the at least one magnetoelectric conversion unit flows via the first terminal portion and the conductor portion;
a signal processing IC which is arranged on a second surface side opposite from a first surface of the conductor portion and has a circuit surface on which the at least one magnetoelectric conversion unit is arranged, the signal processing IC processing a signal output from the at least one magnetoelectric conversion unit;
a second lead frame including a second terminal portion which outputs a signal from the signal processing IC; and
an encapsulating portion which encapsulates, by using mold resin, the at least one magnetoelectric conversion unit, the conductor portion, the signal processing IC, and a part of the second lead frame, wherein
regarding the encapsulating portion, a surface facing the first surface of the conductor portion is a first surface of the encapsulating portion, and a surface exposing another part of the second lead frame is a second side surface, and

$$280 \times {T}_{t}^{- 0.2} \times {ε}^{0.12} < 400$$

is satisfied where Tₜ denotes a distance between a part of the first surface of the conductor portion that is closest to the second side surface of the encapsulating portion and the first surface of the encapsulating portion facing the first surface of the conductor portion; and ε denotes a relative permittivity of the mold resin.

### Item 10

The current sensor according to Item 9, wherein

$$523 \times {T}_{ds}^{- 1} \times {ε}^{0.08} < 400$$

is further satisfied,
where T_{ds} denotes a shortest distance among distances from a first side surface of the encapsulating portion exposing the first terminal portion to the second lead frame or to the signal processing IC.

### Item 11

The current sensor according to Item 9, wherein
regarding the signal processing IC, a surface on the second surface side of the conductor portion is a first surface of the signal processing IC, and a surface on an opposite side from the first surface of the signal processing IC is a second surface,
regarding the encapsulating portion, a surface facing the first surface of the conductor portion is a first surface of the encapsulating portion, a surface facing the second surface of the conductor portion is a second surface of the encapsulating portion, and a surface of the conductor portion exposing the first terminal portion is a first side surface, and

$$470 \times {T}_{b}^{- 1} \times {ε}^{0.08} < 400$$

is further satisfied,
where T_{b} denotes a distance between the second surface of the encapsulating portion and, of the second surface of the signal processing IC or the second surface of the conductor portion, a part closest to the first side surface of the encapsulating portion.

### Item 12

The current sensor according to Item 9, wherein
regarding the signal processing IC, a surface on the second surface side of the conductor portion is a first surface of the signal processing IC, and a surface on an opposite side from the first surface of the signal processing IC is a second surface,
regarding the encapsulating portion, a surface facing the first surface of the conductor portion is a first surface of the encapsulating portion, a surface facing the second surface of the conductor portion is a second surface of the encapsulating portion, and a surface of the conductor portion exposing the first terminal portion is a first side surface, and

$$523 \times {T}_{ds}^{- 1} \times {ε}^{0.08} < 400 and 470 \times {T}_{b}^{- 1} \times {ε}^{0.08} < 400$$

are further satisfied,
where T_{ds} denotes a shortest distance among distances from the first side surface of the encapsulating portion to the second lead frame or to the signal processing IC, and T_{b} denotes a distance between the second surface of the encapsulating portion and, of the second surface of the signal processing IC, a part closest to the first side surface of the encapsulating portion.

### Item 13

The current sensor according to Item 9, wherein
regarding the signal processing IC, a surface on the second surface side of the conductor portion is a first surface of the signal processing IC, and a surface on an opposite side from the first surface of the signal processing IC is a second surface, and
the second lead frame has, on the second surface side of the signal processing IC, a holding portion which holds the signal processing IC.

### Item 14

The current sensor according to any one of Items 1 to 13, wherein
regarding the encapsulating portion, a surface facing the first surface of the conductor portion is a first surface of the encapsulating portion, and a surface facing the second surface of the conductor portion is a second surface of the encapsulating portion,
the conductor portion has: a stepped portion; and a first part on a side of the first surface of the encapsulating portion and a second part on a side of the second surface of the encapsulating portion which are contiguous via the stepped portion, and
the first part is contiguous with the first terminal portion.

### Item 15

The current sensor according to any one of Items 1 to 13, wherein
the first surface of the signal processing IC is the circuit surface, and the at least one magnetoelectric conversion unit is separate from the signal processing IC.

### Item 16

The current sensor according to any one of Items 1 to 13, wherein the signal processing IC incorporates the circuit surface and the at least one magnetoelectric conversion unit.

### Item 17

The current sensor according to any one of Items 1 to 13, wherein the at least one magnetoelectric conversion unit is a Hall element.

### EXPLANATION OF REFERENCE NUMERALS FOR DESIGNATING MAIN COMPONENTS IN THE DRAWINGS

10: current sensor;
20a, 20b: magnetoelectric conversion element;
22a, 22b, 108: wire;
30: insulation tape;
100: signal processing IC;
130: encapsulating portion;
140: lead frame;
141: conductor portion;
142: terminal portion;
150: lead frame;
151: holding portion;
152: terminal portion;
155: stepped portion;
1411, 1412: slit portion.

What is claimed is:

1. A current sensor comprising:
at least one magnetoelectric conversion unit;
a first lead frame which includes a first terminal portion and a conductor portion coupled with the first terminal portion and through which a measurement current measured by the at least one magnetoelectric conversion unit flows via the first terminal portion and the conductor portion;
a signal processing IC which is arranged on a second surface side opposite from a first surface of the conductor portion and has a circuit surface on which the at least one magnetoelectric conversion unit is arranged, the signal processing IC processing a signal output from the at least one magnetoelectric conversion unit;
a second lead frame including a second terminal portion which outputs a signal from the signal processing IC; and
an encapsulating portion which encapsulates, by using mold resin, the at least one magnetoelectric conversion unit, the conductor portion, the signal processing IC, and a part of the second lead frame, wherein
$$523 \times {T}_{ds}^{- 1} \times {ε}^{0.08} < 400$$
is satisfied where T_{ds} denotes a shortest distance among distances from a first side surface of the encapsulating portion exposing the first terminal portion to the second lead frame or to the signal processing IC; and ε denotes a relative permittivity of the mold resin.

2. The current sensor according to claim 1, wherein T_{ds} is 1.6 mm or longer.

3. The current sensor according to claim 1, wherein
regarding the signal processing IC, a surface on the second surface side of the conductor portion is a first surface of the signal processing IC, and a surface on an opposite side from the first surface of the signal processing IC is a second surface, and
the second lead frame has, on the second surface side of the signal processing IC, a holding portion which holds the signal processing IC.

4. The current sensor according to claim 3, wherein the shortest distance T_{ds} is a distance between the first side surface of the encapsulating portion and the holding portion.

5. A current sensor comprising:
at least one magnetoelectric conversion unit;
a first lead frame which includes a first terminal portion and a conductor portion coupled with the first terminal portion and through which a measurement current measured by the at least one magnetoelectric conversion unit flows via the first terminal portion and the conductor portion;
a signal processing IC which is arranged on a second surface side opposite from a first surface of the conductor portion and has a circuit surface on which the at least one magnetoelectric conversion unit is arranged, the signal processing IC processing a signal output from the at least one magnetoelectric conversion unit;
a second lead frame including a second terminal portion which outputs a signal from the signal processing IC; and
an encapsulating portion which encapsulates, by using mold resin, the at least one magnetoelectric conversion unit, the conductor portion, the signal processing IC, and a part of the second lead frame, wherein
regarding the signal processing IC, a surface on the second surface side of the conductor portion is a first surface of the signal processing IC, and a surface on an opposite side from the first surface of the signal processing IC is a second surface,
regarding the encapsulating portion, a surface facing the first surface of the conductor portion is a first surface of the encapsulating portion, a surface facing the second surface of the conductor portion is a second surface of the encapsulating portion, and a surface of the conductor portion exposing the first terminal portion is a first side surface, and
$$470 \times {T}_{b}^{- 1} \times {ε}^{0.08} < 400$$
is satisfied where T_{b} denotes a distance between the second surface of the encapsulating portion and, of the second surface of the signal processing IC or the second surface of the conductor portion, a part closest to the first side surface of the encapsulating portion; and ε denotes a relative permittivity of the mold resin.

6. The current sensor according to claim 5, wherein T_{b} is 1.35 mm or longer.

7. The current sensor according to claim 5, wherein
regarding the signal processing IC, the surface on the second surface side of the conductor portion is the first surface of the signal processing IC, and the surface on the opposite side from the first surface of the signal processing IC is the second surface, and
the second lead frame has, on the second surface side of the signal processing IC, a holding portion which holds the signal processing IC.

8. The current sensor according to claim 7, wherein a height, from the second surface of the encapsulating portion, of a part of the conductor portion that does not overlap with the signal processing IC in a thickness direction is different from a height of the holding portion from the second surface of the encapsulating portion.

9. A current sensor comprising:
at least one magnetoelectric conversion unit;
a first lead frame which includes a first terminal portion and a conductor portion coupled with the first terminal portion and through which a measurement current measured by the at least one magnetoelectric conversion unit flows via the first terminal portion and the conductor portion;
a signal processing IC which is arranged on a second surface side opposite from a first surface of the conductor portion and has a circuit surface on which the at least one magnetoelectric conversion unit is arranged, the signal processing IC processing a signal output from the at least one magnetoelectric conversion unit;
a second lead frame including a second terminal portion which outputs a signal from the signal processing IC; and
an encapsulating portion which encapsulates, by using mold resin, the at least one magnetoelectric conversion unit, the conductor portion, the signal processing IC, and a part of the second lead frame, wherein
regarding the encapsulating portion, a surface facing the first surface of the conductor portion is a first surface of the encapsulating portion, and a surface exposing another part of the second lead frame is a second side surface, and
$$280 \times {T}_{t}^{- 0.2} \times {ε}^{0.12} < 400$$
is satisfied where Tₜ denotes a distance between a part of the first surface of the conductor portion that is closest to the second side surface of the encapsulating portion and the first surface of the encapsulating portion facing the first surface of the conductor portion; and ε denotes a relative permittivity of the mold resin.

10. The current sensor according to claim 9, wherein
$$523 \times {T}_{ds}^{- 1} \times {ε}^{0.08} < 400$$
is further satisfied,
where T_{ds} denotes a shortest distance among distances from a first side surface of the encapsulating portion exposing the first terminal portion to the second lead frame or to the signal processing IC.

11. The current sensor according to claim 9, wherein
regarding the signal processing IC, a surface on the second surface side of the conductor portion is a first surface of the signal processing IC, and a surface on an opposite side from the first surface of the signal processing IC is a second surface,
regarding the encapsulating portion, a surface facing the first surface of the conductor portion is a first surface of the encapsulating portion, a surface facing the second surface of the conductor portion is a second surface of the encapsulating portion, and a surface of the conductor portion exposing the first terminal portion is a first side surface, and
$$470 \times {T}_{b}^{- 1} \times {ε}^{0.08} < 400$$
is further satisfied,
where T_{b} denotes a distance between the second surface of the encapsulating portion and, of the second surface of the signal processing IC or the second surface of the conductor portion, a part closest to the first side surface of the encapsulating portion.

12. The current sensor according to claim 9, wherein
regarding the signal processing IC, a surface on the second surface side of the conductor portion is a first surface of the signal processing IC, and a surface on an opposite side from the first surface of the signal processing IC is a second surface,
regarding the encapsulating portion, a surface facing the first surface of the conductor portion is a first surface of the encapsulating portion, a surface facing the second surface of the conductor portion is a second surface of the encapsulating portion, and a surface of the conductor portion exposing the first terminal portion is a first side surface, and
$$523 \times {T}_{ds}^{- 1} \times {ε}^{0.08} < 400 and 470 \times {T}_{b}^{- 1} \times {ε}^{0.08} < 400$$
are further satisfied,
where T_{ds} denotes a shortest distance among distances from the first side surface of the encapsulating portion to the second lead frame or to the signal processing IC, and T_{b} denotes a distance between the second surface of the encapsulating portion and, of the second surface of the signal processing IC, a part closest to the first side surface of the encapsulating portion.

13. The current sensor according to claim 9, wherein
regarding the signal processing IC, a surface on the second surface side of the conductor portion is a first surface of the signal processing IC, and a surface on an opposite side from the first surface of the signal processing IC is a second surface, and
the second lead frame has, on the second surface side of the signal processing IC, a holding portion which holds the signal processing IC.

14. The current sensor according to claim 1, wherein
regarding the encapsulating portion, a surface facing the first surface of the conductor portion is a first surface of the encapsulating portion, and a surface facing the second surface of the conductor portion is a second surface of the encapsulating portion,
the conductor portion has: a stepped portion; and a first part on a side of the first surface of the encapsulating portion and a second part on a side of the second surface of the encapsulating portion which are contiguous via the stepped portion, and
the first part is contiguous with the first terminal portion.

15. The current sensor according to claim 1, wherein
the first surface of the signal processing IC is the circuit surface, and
the at least one magnetoelectric conversion unit is separate from the signal processing IC.

16. The current sensor according to claim 1, wherein the signal processing IC incorporates the circuit surface and the at least one magnetoelectric conversion unit.

17. The current sensor according to claim 1, wherein the at least one magnetoelectric conversion unit is a Hall element.

18. The current sensor according to claim 12, wherein
regarding the encapsulating portion, a surface facing the first surface of the conductor portion is a first surface of the encapsulating portion, and a surface facing the second surface of the conductor portion is a second surface of the encapsulating portion,
the conductor portion has: a stepped portion; and a first part on a side of the first surface of the encapsulating portion and a second part on a side of the second surface of the encapsulating portion which are contiguous via the stepped portion, and
the first part is contiguous with the first terminal portion.

19. The current sensor according to claim 12, wherein
the first surface of the signal processing IC is the circuit surface, and the at least one magnetoelectric conversion unit is separate from the signal processing IC, or
the signal processing IC incorporates the circuit surface and the at least one magnetoelectric conversion unit.

20. The current sensor according to claim 12, wherein the at least one magnetoelectric conversion unit is a Hall element.
